(19) United States
(12) Patent Application Publication
(10) Pub. No.: US 2025/0083279 A1
(43) Pub. Date: Mar. 13, 2025

(54) POLISHING PROCESS APPARATUS

(71) Applicant: Samsung Electronics Co., Ltd., Suwon-si (KR)

(72) Inventors: Bongwon Ahn, Suwon-si (KR); Eunsil Bae, Suwon-si (KR)

(21) Appl. No.: 18/661,972

(22) Filed: May 13, 2024

(30) Foreign Application Priority Data
Sep. 8, 2023 (KR) 10-2023-0119431

(51) Int. Cl. B24B 49/04; B24B 49/14

(52) U.S. Cl. CPC B24B 49/04; B24B 49/14

(57) ABSTRACT

A polishing process apparatus includes a carrier including a polishing head on which a polishing object is provided, a polishing pad on a lower portion of the carrier, a plurality of temperature sensors on the carrier, and a controller configured to control the carrier, the polishing pad, and the plurality of temperature sensors. The plurality of temperature sensors are in a row in a radial direction, parallel to an upper surface of the polishing head and extending outwardly from a rotation axis of the polishing head. The controller is configured to derive an end point in time of a polishing process using the plurality of temperature sensors and to precisely manage a thickness of the polishing object to be polished, thereby improving reliability of the polishing process apparatus.

### CROSS-REFERENCE TO RELATED APPLICATION(S)

This application claims benefit of priority under 35 U.S.C. § 119 to Korean Patent Application No. 10-2023-0119431 filed on Sep. 8, 2023 in the Korean Intellectual Property Office, the disclosure of which is incorporated herein by reference in its entirety.

### BACKGROUND

The present inventive concept relates to polishing process apparatus.

Among semiconductor processes, a polishing process corresponds to a process of forming a desired thickness by entirely or partially removing a target layer, determined as a wafer or as a layer formed on the wafer. An end point detector (EPD) may be used as a method of checking an end point in time of the polishing process, and the end point in time of the polishing process may be detected using an eddy current or the like. However, a polishing speed may vary depending on a size of each of the grains of the target layer, such that the polishing process may be ended without a portion of the target layer being polished to the desired thickness. Accordingly, a method of precisely detecting the end point in time of the polishing process may be required.

### SUMMARY

An aspect of the present disclosure, as manifested in one or more embodiments, provides a polishing process apparatus capable of measuring, using a plurality of temperature sensors, temperatures respectively corresponding to a plurality of regions into which a polishing object is divided while a polishing process is performed, and deriving temperature change data on each of the plurality of regions using the measured temperatures, thereby accurately determining an end point in time of the polishing process.

According to an aspect of the present inventive concept, there is provided a polishing process apparatus including a polishing object, a carrier including a polishing head on which the polishing object is mounted, a polishing pad disposed on a lower portion of the carrier, a plurality of temperature sensors mounted on the carrier, and a controller configured to control the carrier, the polishing pad, and the plurality of temperature sensors. The plurality of temperature sensors may be disposed in a row in a radial direction, parallel to an upper surface of the polishing head and away from a rotation axis of the polishing head. The controller may determine an end point in time of a polishing process, using, or as a function of, temperatures measured by the plurality of temperature sensors.

According to another aspect of the present inventive concept, there is provided a polishing process apparatus including a polishing object, a carrier including a polishing head on which the polishing object is mounted, a drive shaft configured to rotate the polishing head, and a temperature sensor mounting portion connected to the drive shaft, a polishing pad disposed on a lower portion of the carrier, a plurality of temperature sensors mounted on the temperature sensor mounting portion, and a controller configured to control the carrier, the polishing pad, and the plurality of temperature sensors. The polishing head may have a first radius from a central axis of the polishing head. The plurality of temperature sensors may be disposed along an arc having a second radius from the central axis, and the second radius has a value greater than that of the first radius. The controller may be configured to determine an end point in time of a polishing process using temperatures measured by the plurality of temperature sensors.

According to another aspect of the present inventive concept, there is provided a polishing process apparatus including a polishing object, a carrier including a polishing head on which the polishing object is mounted, a polishing pad disposed on a lower portion of the carrier, a plurality of temperature sensors mounted on the carrier, and a controller configured to control the carrier, the polishing pad, and the plurality of temperature sensors. The polishing object may be divided into a plurality of regions. The plurality of temperature sensors may be configured to respectively measure temperatures corresponding to the plurality of regions, different from each other, while a polishing process is performed. The controller may be configured to receive the measured temperatures and derive temperature data, to calculate temperature change data using the temperature data, and to determine an end point in time of the polishing process using the temperature change data.

### BRIEF DESCRIPTION OF DRAWINGS

The above and other aspects, features, and advantages of the present inventive concept will be more clearly understood from the following detailed description, taken in conjunction with the accompanying drawings, wherein like reference numerals (when used) indicate corresponding elements throughout the several views, and in which:

FIG. 1 is a perspective view of a schematic diagram illustrating at least a portion of a polishing process apparatus according to an example embodiment of the present inventive concept;

FIG. 2 is a schematic block diagram illustrating a polishing process apparatus according to an example embodiment of the present inventive concept;

FIG. 3 is a schematic cross-sectional view of a polishing head according to an example embodiment of the present inventive concept;

FIG. 4 is a schematic exploded perspective view of a polishing head according to an example embodiment, as illustrated in FIG. 3;

FIG. 5 is a schematic plan view of a rotary union according to an example embodiment, as illustrated in FIG. 4;

FIG. 6 is a cross-sectional view of a rotary union according to an example embodiment, as illustrated in FIG. 5, taken along line I-I′;

FIG. 7 is a schematic cross-sectional view of a polishing head according to an example embodiment of the present inventive concept;

FIG. 8 is a schematic plan view of a polishing head according to an example embodiment, as illustrated in FIG. 7;

FIG. 9 is a diagram illustrating a relationship between a plurality of regions and a plurality of temperature sensors according to an example embodiment, as illustrated in FIG. 7;

FIG. 10 is a graph illustrating temperature data and temperature change data according to an example embodiment of the present inventive concept;

FIG. 11 is a flowchart illustrating an operation process of a polishing process apparatus according to an example embodiment of the present inventive concept;

FIGS. 12 to 15 are diagrams illustrating intermediate processes in an example polishing process performed by a polishing process apparatus according to an example embodiment of the present inventive concept;

FIG. 16 is a diagram illustrating a structure of a semiconductor device according to an example embodiment of the present inventive concept; and

FIGS. 17 to 21 are schematic cross-sectional views of a semiconductor device taken along line I-I′ of FIG. 16, and are diagrams illustrating a polishing process performed by a polishing process apparatus according to an example embodiment of the present inventive concept.

### DETAILED DESCRIPTION

Hereinafter, preferred example embodiments of the present inventive concept will be described with reference to the accompanying drawings. The same reference numerals are used to indicate the same components in the drawings, and redundant descriptions thereof may be omitted herein.

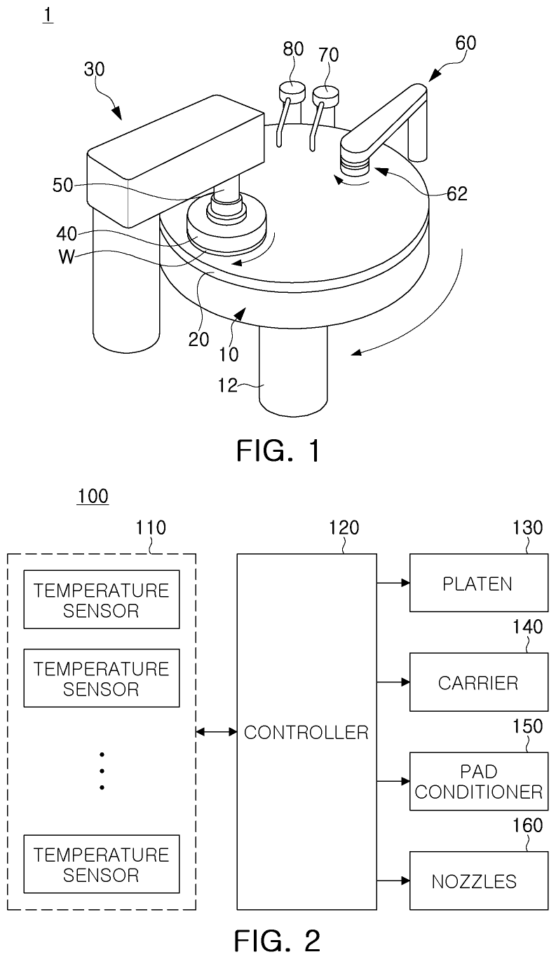

FIG. 1 is a schematic diagram illustrating at least a portion of a polishing process apparatus according to an example embodiment of the present inventive concept.

Referring to FIG. 1, a polishing process apparatus 1 according to an example embodiment of the present inventive concept may include a platen 10 having an upper surface to which a polishing pad 20 is attached, a carrier 30 supporting a polishing object such as a wafer W, a pad conditioner 60 for conditioning a polishing surface, an upper surface of the polishing pad 20, and nozzles 70 and 80 supplying a predetermined material to the polishing pad 20 while the polishing process is performed. In addition, although not explicitly illustrated in FIG. 1, the polishing process apparatus 1 may further include a plurality of temperature sensors and a controller. The plurality of temperature sensors may measure temperature while the polishing process is performed, and the controller may control the platen 10, the polishing pad 20, the carrier 30, the nozzles 70, 80, and the plurality of temperature sensors.

The platen 10 may have a rotatable disk shape on which the polishing pad 20 is seated. The platen 10 may be rotated by a drive shaft 12 having a drive shaft. In the example embodiment illustrated in FIG. 1, the platen 10 and a polishing head 40 may rotate in the same direction, but the present inventive concept is not necessarily limited thereto. One or more nozzles (e.g., nozzles 70 and 80) may discharge abrasive particles to a surface of the polishing pad 20, and the polishing pad 20 may rub against (i.e., contact) the wafer W together with the abrasive particles discharged to the surface to polish and remove a target layer of the wafer W. For example, the polishing pad 20 may include an elastic material such as polyurethane, and may have a rough surface including a plurality of polishing protrusions.

A plurality of semiconductor dies may be disposed to have a grid shape on the wafer W, a polishing object, and each of the plurality of semiconductor dies may include one or more layers. For example, an uppermost layer, among the one or more layers, may be a target layer of the polishing process. The wafer W may be mounted on the carrier 30 such that the target layer is exposed to the outside of the polishing head 40.

The polishing head 40 may be fixed (or otherwise fastened) to a drive shaft 50 of the carrier 30, and may be rotated by the drive shaft 50. The polishing head 40 may include a retainer ring, and the wafer W may be fixed below a membrane within the polishing head 40. The polishing head 40 may press the target layer onto the polishing pad 20.

When the polishing pad 20 is worn, the pad conditioner 60 may regenerate a predetermined level of surface roughness by grinding a surface of the polishing pad 20. Pressure may be applied in a state in which a conditioner disk 62 of the pad conditioner 60 is in contact with the surface of the polishing pad 20. For example, when the polishing pad 20 is used during a predetermined period of time or more, surface properties of the polishing pad 20 may be damaged due to friction with the target layer of the wafer W, and accordingly polishing process speed may be reduced. In this case, constancy of the polishing pad 20 may be maintained by regenerating the polishing pad 20 using the pad conditioner 60.

The nozzles 70 and 80 may include a first nozzle 70 supplying a slurry solution to the upper surface of the polishing pad 20, and a second nozzle 80 supplying a fluid to the upper surface of the polishing pad 20. The slurry solution sprayed from the first nozzle 70 may include a chemical and an abrasive. In an example embodiment, the slurry solution may include fine abrasive particles such as colloidal silica. The target layer of the wafer W may be chemically planarized by the slurry solution sprayed onto the upper surface of the polishing pad 20.

In addition, a temperature of the polishing pad 20 may be adjusted through the second nozzle 80. The second nozzle 80 may supply a fluid for temperature control to the upper surface of the polishing pad 20. For example, the second nozzle 80 may supply deionized water or gas to the upper surface of the polishing pad 20, and the gas may include nitrogen, oxygen, carbon dioxide, or the like.

A deposition process in which a specific material is deposited to form a thin film may be performed on the polishing object including the wafer W. The thin film may not be formed to have the same thickness in all positions of the wafer W, and there may be a difference between the positions in terms of a cross-sectional thickness of the thin film. Accordingly, a polishing process may be performed on the wafer W in order to adjust the thickness of the thin film to a predetermined thickness.

In order to reduce a difference between the positions of the wafer W in terms of a deposition thickness and improve a wafer per day WPD of the wafer W, a grain size may be different for each position of the wafer W. Accordingly, a speed at which the target layer is removed may vary depending on the position of the wafer W, such that the polishing process may be ended without a portion of the wafer W being polished to a desired thickness.

The polishing process apparatus 1 according to an example embodiment of the present inventive concept may include the plurality of temperature sensors. While the polishing process is performed, the controller of the polishing process apparatus 1 may measure temperatures of a plurality of regions into which the polishing object is divided, using the plurality of temperature sensors. The controller may derive an end point in time of the polishing process using (i.e., .as a function of) the temperatures respectively measured with respect to the plurality of regions.

Specifically, the controller may derive, using an output of each of the plurality of temperature sensors, temperature data on each of the plurality of regions of the polishing object, and may determine an end point in time of the polishing process based thereon. For example, the controller may calculate temperature change data using the temperature data from the respective temperature sensors, and may derive the end point in time of the polishing process using the temperature change data.

For example, the temperature data may include temperatures detected at different points in time with respect to each of the plurality of regions. For example, the temperature change data may include amounts of temperature change respectively, from a baseline or reference temperature, detected in the plurality of regions during a predetermined period of time. For example, the end point in time of the polishing process may be determined as a latest point in time, among points in time at which the amounts of temperature change of the plurality of regions respectively converge to zero (0), after a point in time at which the amounts of temperature change of the plurality of regions respectively have a maximum value.

According to an example embodiment of the present inventive concept, temperatures respectively corresponding to the plurality of regions may be measured and an end point in time of the polishing process may be derived using the temperatures, while the polishing process is performed, thereby more precisely determining the end point in time of the polishing process. Accordingly, a thickness of a polishing object to be polished may be accurately managed with the polishing process apparatus 1, thereby maintaining reliability of the polishing process.

FIG. 2 is a schematic block diagram illustrating at least a portion of a polishing process apparatus according to an example embodiment of the present inventive concept.

Referring to FIG. 2, a polishing process apparatus 100 according to an example embodiment of the present inventive concept may include a plurality of temperature sensors 110, a controller 120, a platen 130, a carrier 140, a pad conditioner 150, and one or more nozzles 160. Operations of the platen 130, the carrier 140, the pad conditioner 150, and the nozzles 160 may be understood with reference to the example embodiment described above with reference to FIG. 1.

For example, the controller 120 may rotate each of the carrier 140 and the platen 130 in a state in which a polishing object is fixed to the carrier 140 to remove at least a portion of a target layer included in the polishing object. Alternatively, when the controller 120 determines that a polishing process has been sufficiently performed, the controller 120 may stop rotation of the platen 130 and the carrier 140 and may stop operations of the pad conditioner 150 and the nozzles 160.

In an example embodiment of the present inventive concept, the plurality of temperature sensors 110 may be controlled by the controller 120, and the polishing object may be divided into a plurality of regions. The plurality of temperature sensors 110 may measure temperatures respectively corresponding to the plurality of regions while the polishing process is performed. In an example embodiment of the present inventive concept, the plurality of temperature sensors 110 may measure a temperature of a rear surface of the polishing object in contact with a polishing head, and the controller 120 may measure a temperature of each of the plurality of regions using the temperatures measured by the plurality of temperature sensors 110. In another example embodiment of the present inventive concept, the plurality of temperature sensors 110 may measure a temperature of the polishing pad, and the controller 120 may determine a temperature of a portion of the polishing pad in contact with the polishing object, using the temperature of the polishing pad.

The controller 120 may determine whether the target layer has been sufficiently polished, and may stop the polishing process when the target layer has been sufficiently polished. The controller 120 according to an example embodiment of the present inventive concept may determine an end point in time of the polishing process using temperatures received from the plurality of temperature sensors 110, and the end point in time of the polishing process may be a point in time at which the target layer is determined to be sufficiently polished. Specifically, the controller 120 may receive the respective temperatures measured by the plurality of temperature sensors 110 and derive temperature data, may calculate temperature change data using the temperature data, and may determine an end point in time of the polishing process using the temperature change data.

For example, the temperature data may include temperatures detected at different points in time with respect to each of the plurality of regions. The temperature change data may include amounts of temperature change respectively detected in the plurality of regions during a predetermined period of time, as measured from a base or reference point in time. The end point in time of the polishing process may be a latest point in time, among points in time at which the amounts of temperature change of the plurality of regions respectively converge to zero (0), after a point in time at which the amounts of temperature change of the plurality of regions respectively have a maximum value.

In other words, the controller 120 may determine whether the polishing process has been sufficiently performed in each of the plurality of regions, and may finally end the polishing process when it is determined that the polishing process has been sufficiently performed in all regions. To this end, the controller 120 may determine the end point in time of the polishing process using the plurality of temperature sensors. Accordingly, the polishing process may have improved accuracy by improving a degree of precision of the end point in time of the polishing process.

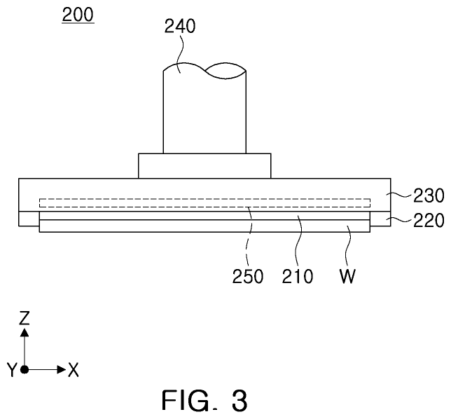

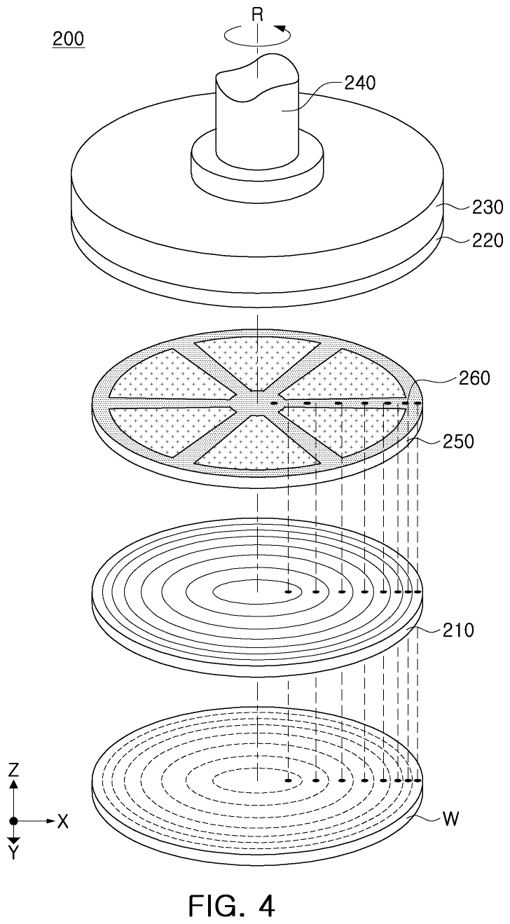

FIG. 3 is a schematic cross-sectional view of a polishing head according to an example embodiment of the present inventive concept. FIG. 4 is a schematic exploded perspective view of a polishing head according to an example embodiment, as illustrated in FIG. 3.

A polishing process apparatus may include a carrier, a polishing pad, and a controller, and the carrier may include a polishing head 200 on which a polishing object is mounted. The polishing pad may be disposed on a lower portion of the carrier. In one or more embodiments, the polishing head 200 may rotate while fixing the wafer W (i.e., while the wafer W is stationary). Alternatively or additionally, in some embodiments, the polishing head 200 may be fixed while the wafer W rotates. In either case, the polishing head 200 may polish and remove a target layer of the wafer W by friction between the wafer W and a polishing pad attached to the polishing head 200. Operations of the carrier and the polishing pad may be understood with reference to the example embodiment described above with reference to FIG. 1.

Referring to FIGS. 3 and 4, the polishing head 200 according to an example embodiment of the present inventive concept may include a membrane 210, a retainer ring 220, a polishing head body 230, and a drive shaft 240. The polishing head body 230 may be fixed to the drive shaft 240, and may be rotated by a drive shaft (not explicitly shown) included in the drive shaft 240.

The membrane 210 and the retainer ring 220 may be mounted on a lower portion of the polishing head body 230. For example, the membrane 210 may be disposed below the polishing head body 230, and the wafer W may be fixed to the polishing head body 230 below the membrane 210. The retainer ring 220 may be disposed on the outside of the polishing head body 230, and may prevent the wafer W from being separated from the membrane 210 during a polishing process.

The polishing head body 230 may include a pressure control (or regulating) device and a rotary union 250. The pressure control device may generate pressure by performing a pumping operation during the polishing process. For example, air may be used. The rotary union 250 may be disposed on a lower portion of the pressure control device. For example, the rotary union 250 may have a plurality of through-holes, and may transmit the pressure generated by the pressure control device to the membrane 210. The membrane 210 may press the wafer W with the received pressure, such that the target layer of the wafer W may be polished by the polishing pad.

Referring to FIG. 4, a polishing object may be the wafer W or at least one layer formed on the wafer W, and each of the membrane 210 and the rotary union 250 may have a disk shape the same as that of the wafer W.

In the example embodiment illustrated in FIG. 4, the wafer W, a polishing object, may be divided into a plurality of regions. Each of the plurality of regions may have a concentric circular shape with respect to a rotation axis R, and a width of each of the plurality of regions may decrease as a distance from the rotation axis R increases. The number and/or shapes of the plurality of regions may not be limited to the example embodiment illustrated in FIG. 4.

Referring to FIG. 4, the membrane 210 may have a plurality of unit regions, and the membrane 210 may be divided into the plurality of unit regions in the same manner as the plurality of regions of the polishing object. In an example embodiment of the present inventive concept, the membrane 210 may press the wafer W with different pressures in each of the plurality of unit regions. Accordingly, a difference between positions of the plurality of regions of the polishing object in terms of polishing process speed may be reduced, and a predetermined polishing rate of each of the plurality of regions may be maintained.

According to an example embodiment of the present inventive concept, the polishing head 200 may include a plurality of temperature sensors 260. For example, as illustrated in FIG. 4, the plurality of temperature sensors 260 may be mounted on the rotary union 250 included in the polishing head 200. For example, the plurality of temperature sensors 260 may be disposed in a row in a radial direction, parallel to an upper surface of the polishing head and away from the rotation axis R of the polishing head. In addition, a distance between adjacent temperature sensors, among the plurality of temperature sensors 260, may decrease as a distance from the rotation axis R increases. However, the number and/or arrangement of the plurality of temperature sensors 260 may not be limited to the example embodiment illustrated in FIG. 4.

In the example embodiment illustrated in FIG. 4, the controller of the polishing process apparatus may measure a temperature of a rear surface of the wafer W, a polishing object, in contact with the polishing head 200, using the plurality of temperature sensors 260. In other words, each of the plurality of temperature sensors 260 may be used to measure the temperatures of a rear surface of the wafer W located at points respectively extending from the temperature sensor in a Z-axis direction of FIG. 4. The controller may measure a temperature of each of the plurality of regions of the wafer W using the temperatures measured by the plurality of temperature sensors 260. The number of the plurality of regions of the wafer W may be the same as the number of the plurality of temperature sensors 260.

In an example embodiment of the present inventive concept, the controller may determine an end point in time of the polishing process using the temperatures measured by the plurality of temperature sensors 260. The membrane 210 may apply different pressures to each of the plurality of regions of the wafer W, and thus the plurality of regions of the wafer W may have different end points of the polishing process. Accordingly, a temperature of each of the regions of the wafer W, corresponding to the regions of the membrane 210, may be measured, and the end point in time of the polishing process may be finally determined using the temperature.

The controller according to an example embodiment of the present inventive concept may derive temperature data including temperatures detected at different points in time with respect to each of the plurality of regions of the wafer W, and may calculate temperature change data including amounts of temperature change respectively detected in the plurality of regions during a predetermined period of time (e.g., measured from a base or reference time to a prescribed time thereafter). The controller may determine, as an end point in time of the polishing process, a latest point in time, among points in time at which the amounts of temperature change of the plurality of regions respectively converge to 0, after a point in time at which the amounts of temperature change of the plurality of regions respectively have a maximum value.

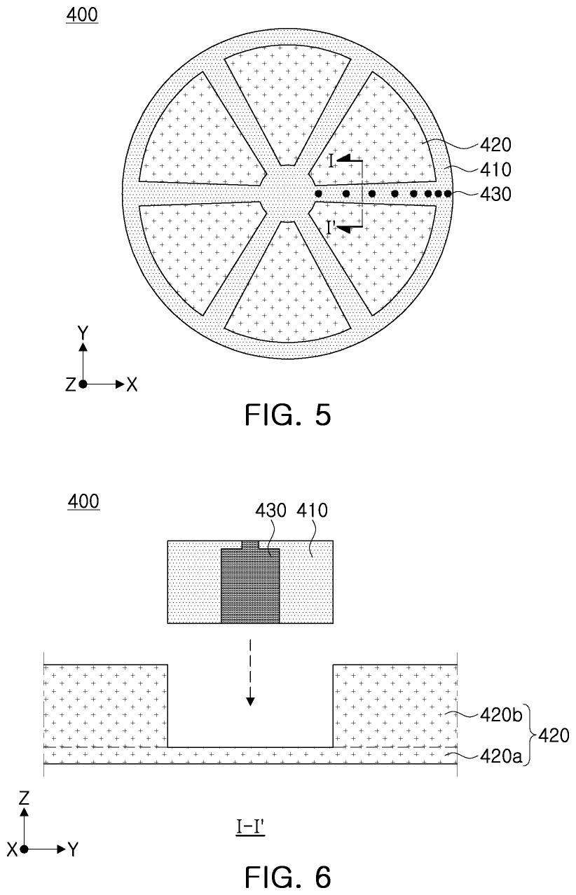

FIG. 5 is a schematic plan view of a rotary union according to an example embodiment, illustrated in FIG. 4. FIG. 6 is a cross-sectional view of the rotary union according to an example embodiment, as illustrated in FIG. 5, taken along line I-I′.

A carrier may include a polishing head, and the polishing head may include a membrane, a retainer ring, a polishing head body, and a drive shaft. Operations of the carrier and the polishing head may be understood with reference to the example embodiment described above with reference to FIGS. 1 and 3.

The polishing head body may include a rotary union 400 and a pressure regulating device, and the rotary union 400 may be disposed on a lower portion of the pressure regulating device. The rotary union 400 may transmit pressure, generated by the pressure regulating device, to the membrane, allowing a wafer to be polished by the transmitted pressure.

First, referring to FIG. 5, the rotary union 400 may include a first rotary union structure 410 and a second rotary union structure 420. The first rotary union structure 410 and the second rotary union structure 420 may have corresponding structures to be coupled and engaged with each other in a Z-axis direction of FIG. 5. For example, the first rotary union structure 410 and the second rotary union structure 420 may be coupled to each other to have a disk shape.

In an example embodiment of the present inventive concept, the first rotary union structure 410 may have a disk shape including a plurality of empty spaces therein. For example, the first rotary union structure 410 may include a circular central structure with respect to a rotation axis R. The plurality of empty spaces may be divided into a plurality of structures (e.g., spokes) connecting, to each other, the central structure and the outside (i.e., perimeter) of the first rotary union structure 410 in radial directions.

The second rotary union structure 420 according to an example embodiment of the present inventive concept may have a structure corresponding to that of the first rotary union structure 410 in the Z-axis direction of FIG. 5. Referring to FIG. 6, the second rotary union structure 420 (420a and 420b) may include a bottom structure 420a having a disk shape, and a coupling structure 420b configured to be coupled and engaged with the first rotary union structure 410.

In an example embodiment of the present inventive concept, the first rotary union structure 410 may include a plurality of temperature sensors 430, and the plurality of temperature sensors 430 may be disposed in a row (in plan view) spaced apart from one another in a radial direction, away from the rotation axis R. A distance between adjacent temperature sensors, among the plurality of temperature sensors 430, may decrease as a distance from the rotation axis R increases, although embodiments are not limited thereto.

According to an example embodiment of the present inventive concept, the plurality of temperature sensors 430 may be provided (e.g., mounted) on the first rotary union structure 410 to measure temperatures respectively corresponding to a plurality of regions of a rear surface of the wafer. A controller may determine, using the measured temperatures, a point in time at which a polishing process for each of the plurality of regions ends, thereby improving a degree of precision of a polishing process apparatus.

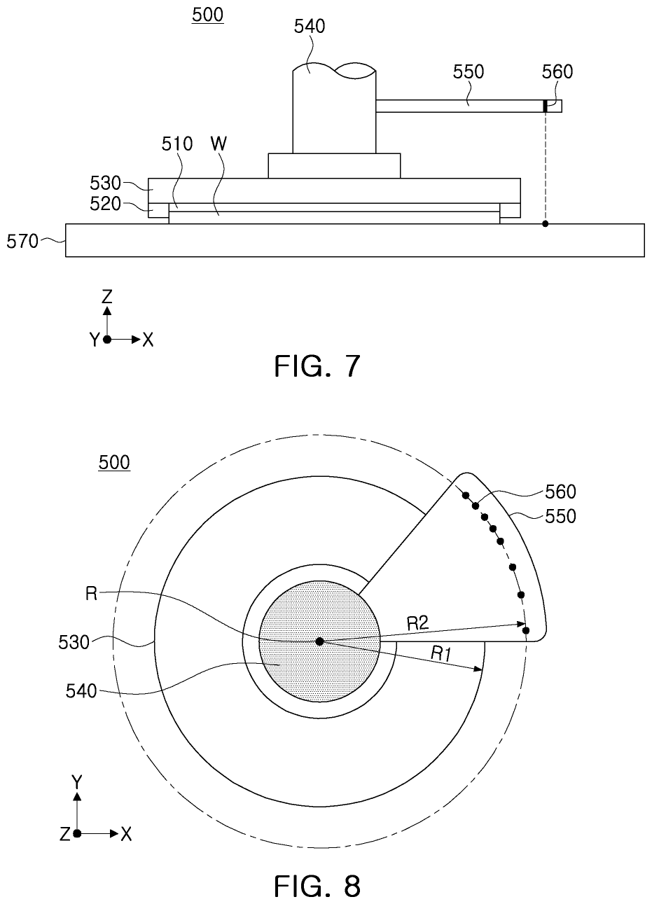

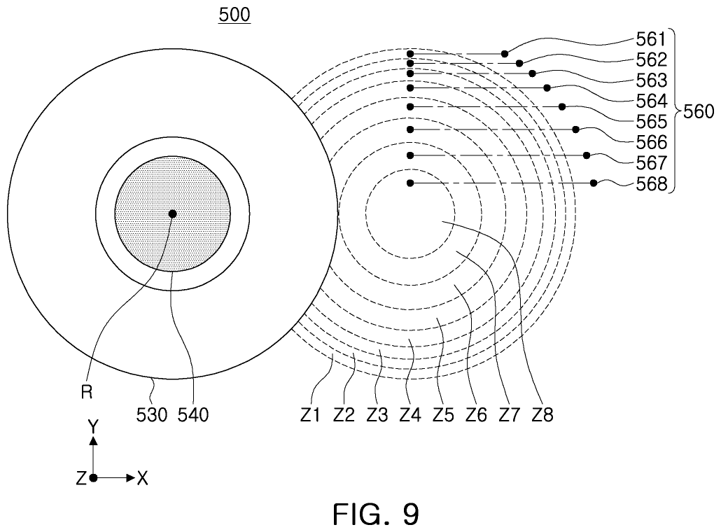

FIG. 7 is a schematic cross-sectional view of at least a portion of a polishing head according to an example embodiment of the present inventive concept. FIG. 8 is a schematic plan view of the polishing head according to an example embodiment, as illustrated in FIG. 7. FIG. 9 is a diagram illustrating a relationship between a plurality of regions and a plurality of temperature sensors according to an example embodiment, as illustrated in FIG. 7.

The polishing process apparatus may include a carrier, a polishing pad 570, and a controller, and the carrier may include a polishing head 500 on which a wafer W, a polishing object, is mounted. Operations of the carrier, the polishing pad 570, and the controller may be understood with reference to the example embodiment described above with reference to FIG. 1.

First, referring to FIG. 7, the polishing head 500 according to an example embodiment of the present inventive concept may include a membrane 510, a retainer ring 520, a polishing head body 530, and a drive shaft 540. As compared to the polishing head 200 according to an example embodiment of the present inventive concept in FIG. 3, the polishing head 500 in FIG. 7 may further include a temperature sensor mounting portion 550. The polishing head body 530 may have a first radius R1 from a rotation axis R. In other words, the polishing head 500 may have a first radius R1 from the rotation axis R. Operations of the membrane 510, the retainer ring 520, the polishing head body 530, and the drive shaft 540 may be understood with reference to the example embodiment described above with reference to FIGS. 3 and 4.

Referring to FIGS. 7 and 8, the temperature sensor mounting portion 550 according to an example embodiment of the present inventive concept may be connected to the drive shaft 540. A plurality of temperature sensors 560 may be mounted on the temperature sensor mounting portion 550. Referring to FIG. 8, the plurality of temperature sensors 560 may be disposed along an arc having a second radius R2 from the rotation axis R, and the second radius R2 may have a value greater than that of the first radius R1. In addition, in a radial direction, parallel to an upper surface of the polishing head and away from the rotation axis R of the polishing head, a distance between the temperature sensors disposed on the outside of the plurality of temperature sensors 560 may be shorter than the second radius R2.

Referring to FIG. 7, the plurality of temperature sensors 560 may be disposed to have the same height, in a vertical direction (Z direction), from the polishing pad 570.

In the example embodiment illustrated in FIG. 7, the plurality of temperature sensors 560 may be disposed along an arc having the second radius R2 greater than the first radius R1, such that the plurality of temperature sensors 560 may measure a temperature of the polishing pad 570, which may extend radially (in an X direction) beyond the wafer W; that is, a radius of the polishing pad 570 may be greater than a radius of the wafer W. Specifically, the controller may determine, using the temperatures measured by the plurality of temperature sensors 560, a temperature of a portion of the polishing pad 570 in contact with the wafer W, a polishing object.

In an example embodiment of the present inventive concept, the wafer W, a polishing object, may be mounted on a lower portion of the polishing head 500, and may be arranged to be in contact with a portion of the polishing pad 570 during a polishing process. The wafer W may be divided into a plurality of regions, and the controller may determine, using temperatures measured by the plurality of temperature sensors 560, a temperature of a portion of the polishing pad 570 in which each of the plurality of regions is in contact with the wafer W.

In the example embodiment illustrated in FIG. 9, the wafer W, a polishing object, may be divided into a plurality of polishing regions or zones Z1 to Z8, and each of the plurality of regions Z1 to Z8 may have a concentric circle shape with respect to a rotation axis. A width of each of the plurality of regions Z1 to Z8 may decrease as a distance from the rotation axis increases.

A direction of movement of the polishing head body 530 may be a direction from a right side to a left side with respect to an X-axis direction in FIG. 9. In other words, a position of the polishing head body 530 may be a position in which a polishing process is currently being performed, and positions of the plurality of regions Z1 to Z8 may be positions in which a past polishing process of the polishing head body 530 was performed. The plurality of temperature sensors 560 may be disposed as in the example embodiment illustrated in FIG. 8. As the polishing head body 530 moves, the plurality of temperature sensors 560 may respectively measure temperatures corresponding to the plurality of regions Z1 to Z8. In other words, the controller may determine, using the temperatures measured by the plurality of temperature sensors 560, a temperature of a portion of the polishing pad in which each of the plurality of regions Z1 to Z8 is in contact with the wafer W.

In an example embodiment of the present inventive concept, the number of regions Z1 to Z8 may be the same as the number of temperature sensors 560 (561 to 568). According to the example embodiment illustrated in FIGS. 8 and 9, the number of the plurality of regions Z1 to Z8 and the number of the plurality of temperature sensors 560 (561 to 568) may be eight, respectively, but the present inventive concept is not limited thereto. For example, the first temperature sensor 561 may measure a temperature of a first region Z1 in contact with the wafer W, a polishing object. Thus, second to eighth temperature sensors 562 to 568 may respectively measure temperatures of second to eighth regions Z2 to Z8 in contact with the wafer W, a polishing object.

The controller according to an example embodiment of the present inventive concept may determine, using the temperatures measured by the plurality of temperature sensors 560, the temperature of a portion of the polishing pad in which each of the plurality of regions Z1 to Z8 is in contact with the wafer W, a polishing object. The controller may determine, using the temperatures measured by the plurality of temperature sensors 560, whether a polishing process for each of the plurality of regions Z1 to Z8 has been ended. When it is determined that the polishing process has been ended in all of the plurality of regions Z1 to Z8, an end point in time of the polishing process may be more precisely determined. Accordingly, a thickness of a polishing object to be polished with the polishing process apparatus may be accurately managed, thereby improving reliability of the polishing process.

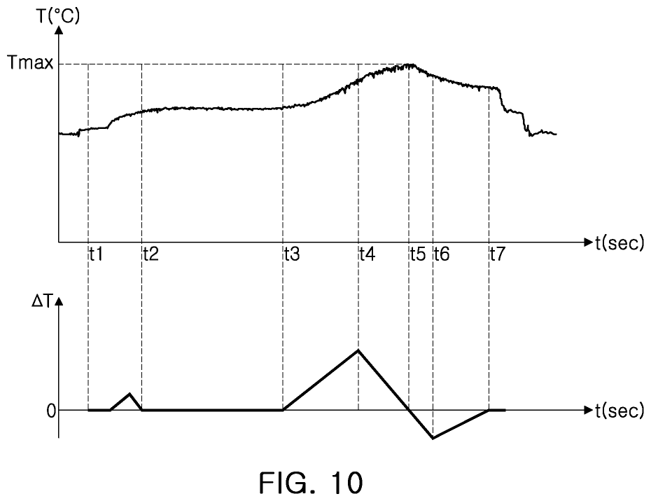

FIG. 10 is a graph illustrating temperature data and temperature change data according to an example embodiment of the present inventive concept.

A polishing process apparatus according to the present inventive concept may include a polishing object, a carrier including a polishing head on which the polishing object is mounted, a polishing pad disposed on a lower portion of the carrier, a plurality of temperature sensors mounted on the carrier, and a controller. The controller may control the carrier, the polishing pad, and a plurality of temperature sensors. The polishing object according to the present inventive concept may be divided into a plurality of regions. The plurality of temperature sensors may respectively measure temperatures corresponding to the plurality of regions, different from each other, while a polishing process is performed.

The controller according to the present inventive concept may receive the temperatures measured from the plurality of temperature sensors and derive temperature data. In addition, the controller may calculate temperature change data using the temperature data, and may determine an end point in time of the polishing process using the temperature change data.

A first (upper) graph in FIG. 10 may be temperature data of one region, among the plurality of regions. For example, the temperature data may include temperatures detected at different points in time for the one region. Referring to the first graph of FIG. 10, the temperature data may represent a temperature T of the one region based on points in time t. The unit of the points in time t may be seconds (sec), and the unit of the temperature T may be degrees Celsius (° C.).

A second (lower) graph in FIG. 10 may be temperature change data of one region, among the plurality of regions. For example, temperature change data may include amounts of temperature change detected with respect to the one region during a predetermined period of time. For example, the controller may calculate temperature change data by differentiating temperature data with respect to time. Referring to the second graph of FIG. 10, the temperature change data may represent an amount of temperature change ΔT of the one region based on the predetermined period of time. The unit of the predetermined period of time may be seconds, and the unit of the amount of temperature change ΔT may be degrees Celsius (° C.).

Referring to the first graph of FIG. 10, a polishing process may be started at a first point in time t1 and a target layer of a polishing object may be polished. After the first point in time t1, the temperature T may continue to rise as the polishing process is performed. At a second point in time t2, an entire rough surface of an upper portion of the target layer may be polished. A predetermined value of the temperature T may be maintained until a third point in time t3, and the temperature T may rise again after the third point in time t3. Referring to the second graph of FIG. 10, the amount of temperature change ΔT may have a maximum value at a fourth point in time t4. Thereafter, the amount of temperature change ΔT may decrease.

As the polishing process is continually performed, an insulating film may be firstly exposed at a fifth point in time t5. At the fifth point in time t5, the temperature T may have a maximum value Tmax, and the amount of temperature change ΔT may have a value of 0. As the polishing process is continually performed after the fifth point in time t5, the temperature T may decrease and the amount of temperature change after time t5 may be less than 0. At a sixth point in time t6, the amount of temperature change ΔT may have a minimum value.

After a seventh point in time t7, a section in which the temperature T reaches a predetermined value may occur. After the seventh point in time t7, the amount of temperature change ΔT may converge to 0. The controller according to the present inventive concept may determine, as an end point in time of a corresponding region, a point in time at which an amount of temperature change converges to 0 after a point at which the amount of temperature change has a maximum value. According to the example embodiment illustrated in FIG. 10, the seventh point in time t7 may be an end point in time of the corresponding region.

As in the example embodiment illustrated in FIG. 10, the controller may respectively calculate end points in time with respect to the plurality of regions, using the temperature data and the temperature change data. Accordingly, the controller may determine a latest point in time, among the end points in time of the plurality of regions, as an end point in time of the polishing process.

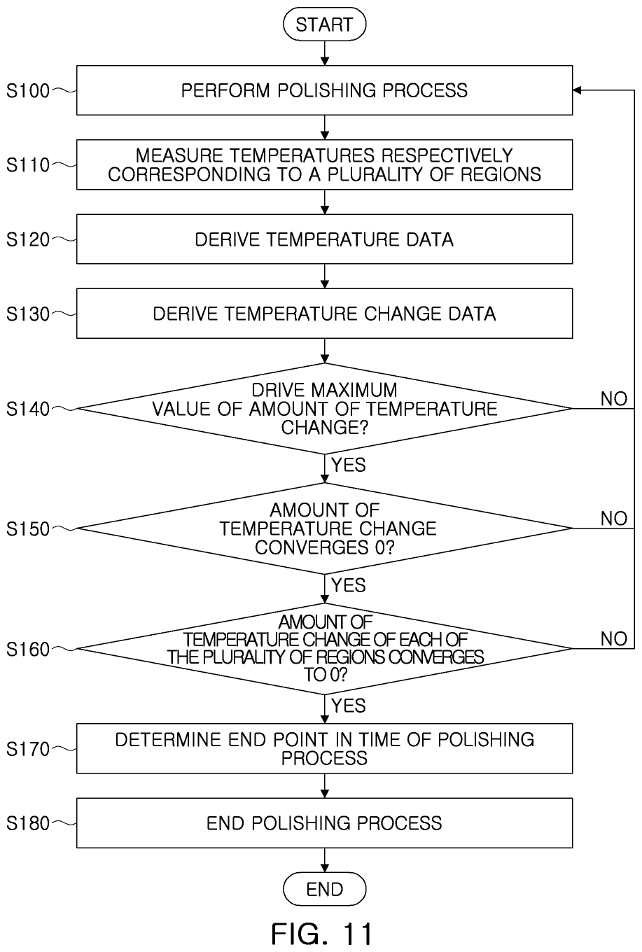

FIG. 11 is a flowchart illustrating an operation process of a polishing process apparatus according to an example embodiment of the present inventive concept.

The polishing process apparatus according to the present inventive concept may include a polishing object, a carrier, a polishing pad, a plurality of temperature sensors, and a controller. The carrier may include a polishing head on which the polishing object is mounted, and the polishing pad may be disposed on a lower portion of the carrier. The controller may control the carrier, the polishing pad, and the plurality of temperature sensors.

The plurality of temperature sensors may be mounted on the carrier. According to an example embodiment of the present inventive concept, the plurality of temperature sensors may be mounted on a rotary union included in the polishing head. A specific example embodiment of the plurality of temperature sensors may be similar to those described with reference to FIGS. 3 to 6. According to an example embodiment of the present inventive concept, the polishing head may include a temperature sensor mounting portion, and the plurality of temperature sensors may be mounted on the temperature sensor mounting portion. The specific example embodiment of the plurality of temperature sensors may be similar to that described with reference to FIGS. 7 to 9.

An example method of polishing an object using the polishing process apparatus according to the present inventive concept will now be described with reference to FIG. 11. First, the polishing object may be mounted on the polishing head to perform a polishing process (S100). The polishing object according to the present inventive concept may be divided into a plurality of regions, and the plurality of temperature sensors may respectively measure temperatures corresponding to the plurality of regions while the polishing process is performed (S110).

The controller may receive the temperatures measured by the plurality of temperature sensors and derive temperature data (S120). For example, the temperature data may include temperatures detected at different points in time with respect to each of the plurality of regions, and a specific example embodiment may be similar to that illustrated in the first graph of FIG. 10.

Thereafter, the controller may calculate temperature change data using the temperature data (S130). For example, the temperature change data may include amounts of temperature change detected in each of the plurality of regions during a predetermined period of time. As another example, the controller may calculate temperature change data by differentiating the temperature data with respect to time. A specific example embodiment of the temperature change data may be similar to that illustrated in the second graph of FIG. 10.

The controller may determine whether a maximum value of an amount of temperature change has been derived in each of the plurality of regions (S140). When the maximum value of the amount of temperature change is not derived (“NO” in S140), the controller may continually perform a polishing process for a corresponding region (S100). When the maximum value of the amount of temperature change is derived (“YES” in S140), the controller may determine whether an amount of temperature change for the corresponding region converges to 0 (S150). When the amount of temperature change does not converge to 0 (“NO” in S150), the controller may continually perform the polishing process for the corresponding region (S100).

When the amount of temperature change converges to 0 (“YES” in S150), the controller may determine whether an amount of temperature change of each of the plurality of regions converges to 0 (S160). When an amount of temperature change of at least one region does not converge to 0 (“NO” in S160), the controller may continually perform the polishing process (S100). When the amount of temperature change of each of the plurality of regions converges to 0 (“YES” in S160), the controller may determine an end point in time of the polishing process (S170). The controller according to an example embodiment of the present inventive concept may determine, as the end point in time of the polishing process, a latest point in time, among points in time at which amounts of temperature change of the plurality of regions respectively converge to 0, after a point in time at which the amounts of temperature change of the plurality of regions respectively have a maximum value. In an example embodiment of the present inventive concept, the controller may end the polishing process when the end point in time of the polishing process is determined (S180).

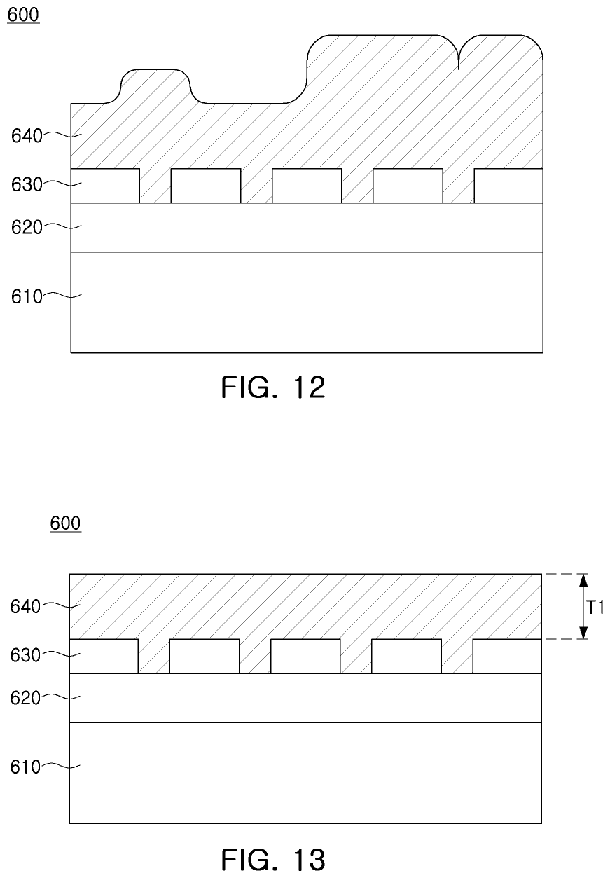

FIGS. 12 to 15 are diagrams illustrating intermediate processes in an example polishing process performed by a polishing process apparatus according to an example embodiment of the present inventive concept.

Referring to FIGS. 12 to 15, a polishing object 600, a target of a polishing process, may include a semiconductor substrate 610 and a plurality of layers 620 to 640 sequentially stacked on the semiconductor substrate 610 in a vertical direction perpendicular to an upper surface of the substrate 610. The polishing process may be performed on a target layer 640 formed on a highest vertical level with respect to the upper surface of the substrate 610 being a reference base layer, among the plurality of layers 620 to 640. For example, the target layer 640 may be formed of a conductive material.

FIG. 12 may be a schematic diagram illustrating a polishing object 600 before the polishing process is started. Referring to FIG. 12, before the polishing process is started, the target layer 640 may have various cross-sectional thicknesses depending on a horizontal position of the polishing object 600 that is being measured. For example, a purpose of the polishing process described with reference to FIGS. 12 to 15 may be to expose patterns of a third layer 630 by removing a portion of the target layer 640.

For example, referring to FIG. 13, during a first period of time after the polishing process is started, a portion of the target layer 640 may be removed to have a predetermined first cross-sectional thickness T1, which may be a vertical distance between an upper surface of the target layer 640 and an upper surface of the underlying third layer 630.

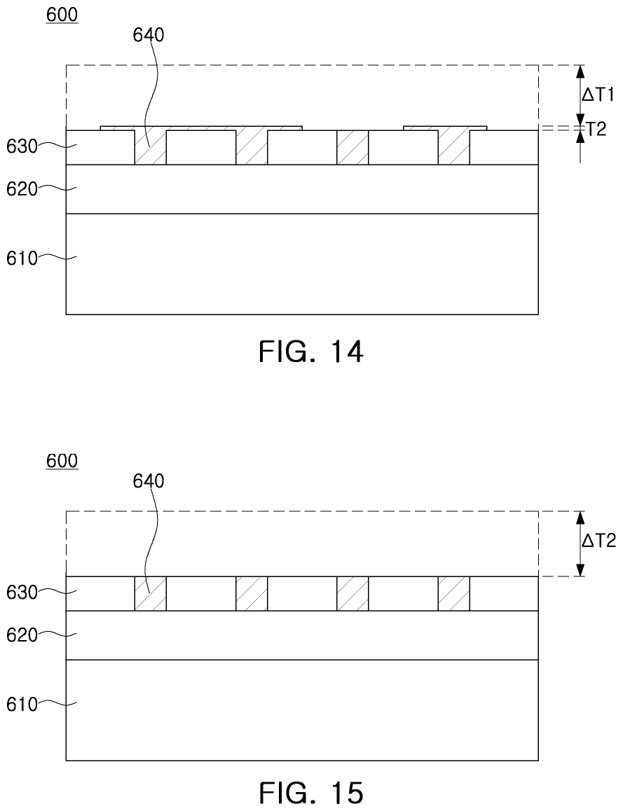

In the example embodiment of the present inventive concept illustrated in FIG. 14, during a second period of time after the polishing process is started, a portion of the target layer 640 may be removed by an amount of change in first thickness ΔT1, such that a thickness of the target layer 640 may decrease from a first thickness T1 to a second thickness T2, as measured from the upper surface of the third layer 630. However, the third layer 630 may be exposed in another portion of the target layer 640.

A controller of a polishing process apparatus according to an example embodiment of the present inventive concept may measure temperatures corresponding to a plurality of regions of the polishing object 600, and may determine whether a polishing process for each of the plurality of regions has been ended. In the example embodiment of the present inventive concept illustrated in FIG. 14, the controller may determine that a polishing process for a portion of the target layer 640 has not been ended (since all of the upper surface of the third layer 630 is not exposed), and may continually perform the polishing process.

Referring to FIG. 15, after a third period of time, the target layer 640 may be removed by an amount of change in second thickness ΔT2, such that the third layer 630 may be exposed in all regions of the polishing object 600. Accordingly, the controller according to an example embodiment of the present inventive concept may determine that the polishing process has been ended in each of the plurality of regions.

The controller according to an example embodiment of the present inventive concept may determine, as the end point in time of the polishing process, a latest point in time, among points in time at which amounts of temperature change of the plurality of regions respectively converge to 0, after a point in time at which the amounts of temperature change of the plurality of regions respectively have a maximum value. Thereafter, the controller may end the polishing process when the end point in time of the polishing process is determined.

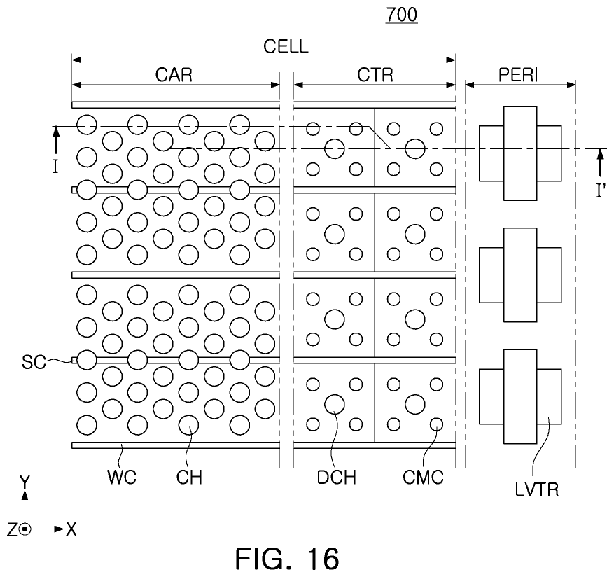

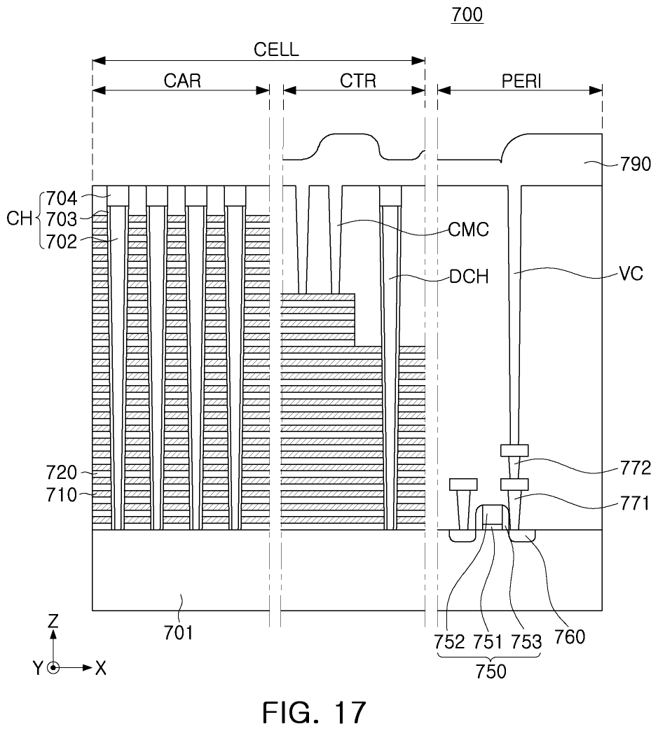

FIG. 16 is a diagram illustrating a structure of a semiconductor device according to an example embodiment of the present inventive concept. FIGS. 17 to 21 illustrate a cross-section of a semiconductor device taken along line I-I′ of FIG. 16, and are diagrams illustrating a polishing process performed by a polishing process apparatus according to an example embodiment of the present inventive concept.

First, FIG. 16 may be a plan view of a portion of a semiconductor device 700 according to an example embodiment of the present inventive concept. Referring to FIG. 16, the semiconductor device 700 may have a cell region CELL and a peripheral circuit region PERI, and the cell region CELL may have a cell array region CAR and a cell contact region CTR. For example, the cell array region CAR may be a region in which channel structures CH are disposed, and the cell contact region CTR may be a region in which cell contacts CMC are disposed. In the example embodiment illustrated in FIG. 16, the cell contact region CTR may be disposed between the cell array region CAR and the peripheral circuit region PERI.

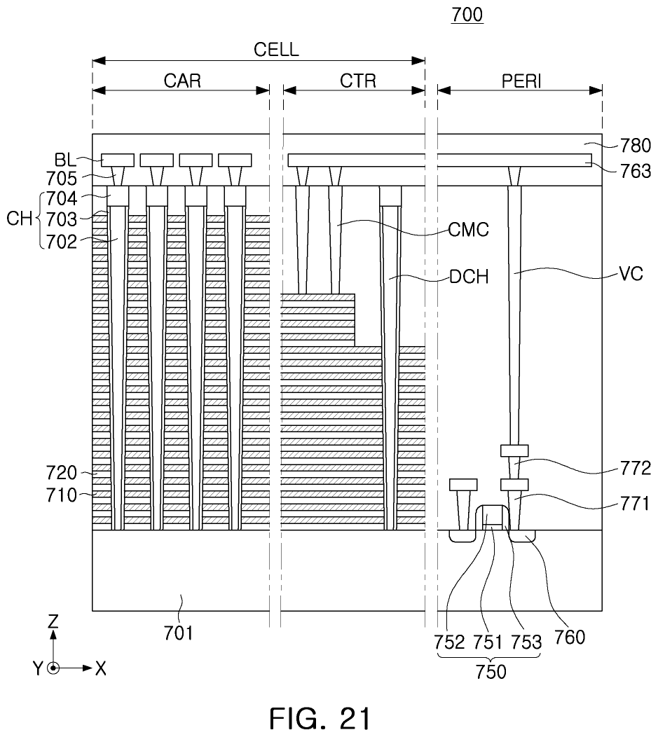

Referring to FIGS. 16 and 21 together, the cell array region CAR may include gate electrode layers 710 and insulating layers 720 alternately stacked in a first direction (Z-axis direction), perpendicular to an upper surface of a substrate 701, and channel structures CH extending in the first direction and passing through the gate electrode layers 710 and the insulating layers 720. Each of the channel structures CH may include a channel layer 702 connected to the substrate 701, a gate dielectric layer 703 between the channel layer 702 and the gate electrode layers 710, and a drain region 704. The term “connected” (or “connecting,” “contact,” “contacting,” or like terms), as may be used herein, is intended to broadly refer to a physical and/or electrical connection between two or more elements, and may include other intervening elements unless the context indicates otherwise. The gate dielectric layer 703 may include a tunneling layer, a charge storage layer, and a blocking layer, and at least one of the layers included in the gate dielectric layer 703 may be formed to surround the gate electrode layers 710. The term “surround” (or “surrounding” or like terms, such as “enclose”), as may be used herein, is intended to broadly refer to an element, structure or layer that extends around, envelops, encircles, or encloses another element, structure or layer on all sides, although breaks or gaps may also be present. The drain region 704 may be connected to one or more bit lines BL via a corresponding bit line contact 705, and the bit lines BL may be connected to a page buffer (not explicitly shown) formed in the peripheral circuit region PERI.

The cell contact region CTR may include cell contacts CMC connected to the gate electrode layers 710, and dummy channel structures DCH. The dummy channel structures DCH may have a structure the same as that of the channel structures CH, and may not be connected to the bit lines BL, unlike the channel structures CH. The gate electrode layers 710 may form a step in at least one of a second direction (X-axis direction) and a third direction (Y-axis direction), the second and third directions being parallel to an upper surface of the substrate 701, in the cell contact region CTR. The cell contacts CMC may be connected to the gate electrode layers 710, and may be connected to a row decoder (not explicitly shown) formed in the peripheral circuit region PERI by word lines 763. The word lines 763 may be formed within an interlayer insulating layer 780, formed in the cell region CELL and the peripheral circuit region PERI.

A row decoder formed in the peripheral circuit region PERI may be disposed to be adjacent to the cell region CELL in the second direction. Referring to FIG. 21, the row decoder may include elements, for example, low-voltage elements LVTR (FIG. 16). Each of the elements may include a gate structure 750 and a source/drain region 760. The elements may provide pass elements directly connected to the word lines 763 via vertical contacts VC. An element contact 771 and lower interconnection lines 772 may be connected to the source/drain region 760, and the gate structure 750 may also be connected to a gate contact.

With reference to FIGS. 17 to 20, a polishing process performed by a polishing process apparatus according to an example embodiment of the present inventive concept will be described. Referring to FIGS. 17 to 20, the semiconductor device 700 may be a polishing object. After a polishing process for a target layer 790 of the semiconductor device 700 is completed, cell contacts CMC and vertical contacts VC may be formed.

FIG. 17 may be a schematic diagram illustrating the semiconductor device 700 before the polishing process is started. Referring to FIG. 17, before the polishing process is started, the target layer 790 may have various cross-sectional thicknesses depending on a position of the semiconductor device 700; that is, the target layer 790 may have different vertical heights, relative to an upper surface of the substrate 701, depending on where along the second direction (X direction) the target layer 790 is measured. For example, a purpose of the polishing process described with reference to FIGS. 17 to 20 may be to expose an interlayer insulating layer by removing the target layer 790.

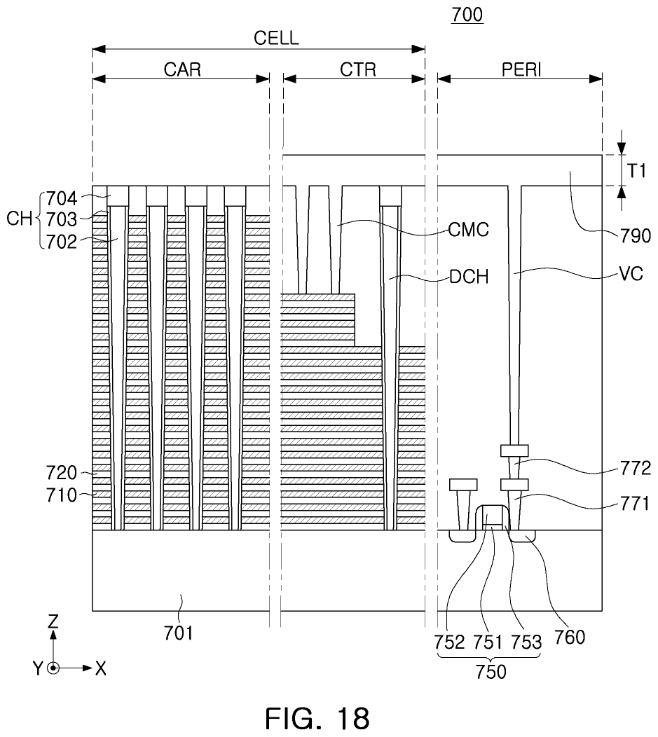

For example, referring to FIG. 18, during a first time after the polishing process is started, a portion of the target layer 790 may be removed to have a predetermined first cross-sectional thickness T1.

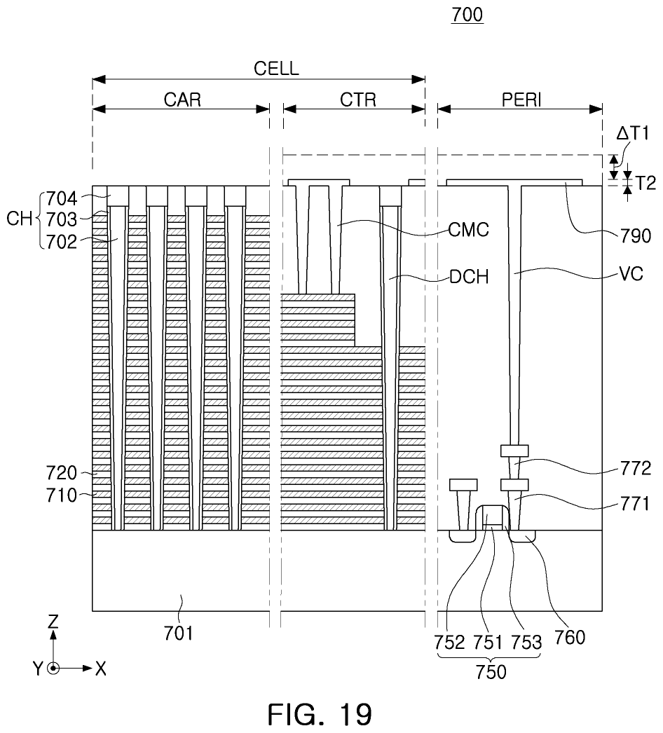

I In the example embodiment of the present inventive concept illustrated in FIG. 19, during a second period of time after the polishing process is started, a portion of the target layer 790 may be removed by an amount of change in first thickness ΔT1, such that a cross-sectional thickness of the target layer 790 may be reduced from the first cross-sectional thickness T1 to a second cross-sectional thickness T2. However, the interlayer insulating layer may be exposed in another portion of the target layer 790.

A controller of the polishing process apparatus according to an example embodiment of the present inventive concept may measure temperatures corresponding to a plurality of regions of the semiconductor device 700, and may determine, using the temperatures, whether a polishing process for each of the plurality of regions is ended. In an example embodiment of the present inventive concept illustrated in FIG. 19, the controller may determine that the polishing process has not been ended for a portion of the target layer 790, and may continually perform the polishing process.

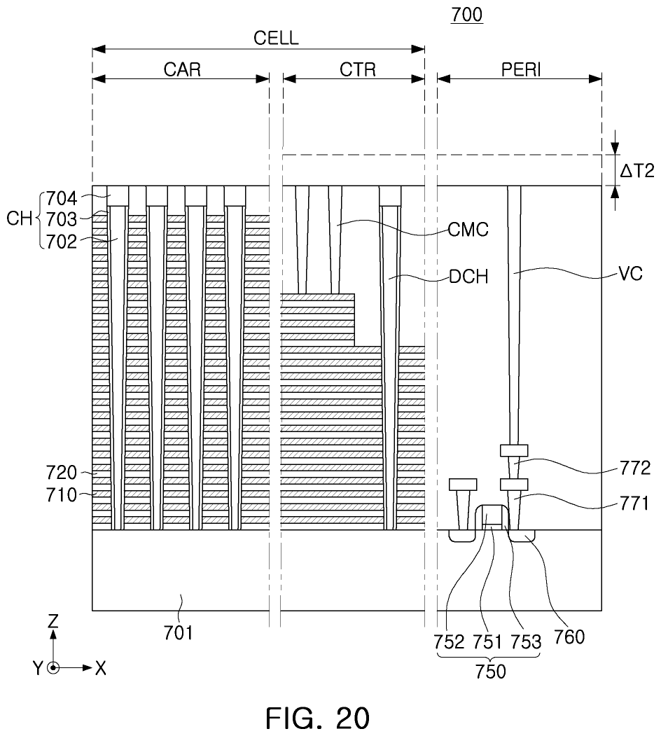

Referring to FIG. 20, after a third period of time, the target layer 790 may be removed by an amount of change in second thickness ΔT2, such that the interlayer insulating layer may be exposed in all regions of the semiconductor device 700. Accordingly, the controller according to an example embodiment of the present inventive concept may determine that the polishing process has been ended in each of the plurality of regions.

The controller according to an example embodiment of the present inventive concept may determine, as an end point in time of the polishing process, a latest point in time, among points in time at which amounts of temperature change of the plurality of regions respectively converge to 0, after a point in time at which the amounts of temperature change of the plurality of regions respectively have a maximum value. Thereafter, the controller may end the polishing process when the end point in time of the polishing process is determined.

After the polishing process of the example embodiment illustrated in FIG. 20 is ended, the semiconductor device 700 according to the example embodiment illustrated in FIG. 21 may be produced via a series of semiconductor processes.

According to an example embodiment of the present inventive concept, temperatures of a plurality of regions of a polishing object may be measured using a plurality of temperature sensors, while a polishing process is performed, thereby precisely detecting an end point in time of the polishing process.

While example embodiments have been shown and described above, it will be apparent to those skilled in the art that modifications and variations could be made without departing from the scope of the present inventive concept as defined by the appended claims.

What is claimed is:

1. A polishing process apparatus, comprising:
a carrier including a polishing head configured to receive a polishing object;
a polishing pad on a lower portion of the carrier;
a plurality of temperature sensors on the carrier; and
a controller configured to control the carrier, the polishing pad, and the plurality of temperature sensors,
wherein the plurality of temperature sensors are configured in a row in a radial direction, parallel to an upper surface of the polishing head and extending outwardly from a rotation axis of the polishing head, and
the controller is configured to determine an end point in time of a polishing process, using temperatures measured by the plurality of temperature sensors.

2. The polishing process apparatus of claim 1, wherein the plurality of temperature sensors are configured to measure a temperature of a rear surface of the polishing object in contact with the polishing head.

3. The polishing process apparatus of claim 2, wherein
the polishing object includes a plurality of regions, and
the controller is configured: to determine a temperature of each of the plurality of regions of the polishing object, using the temperatures measured by the plurality of temperature sensors; to calculate respective temperature change data for each of the plurality of regions based on the temperatures measured by the plurality of temperature sensors; and to determine the end point in time of the polishing process based on the respective temperature change data.

4. The polishing process apparatus of claim 3, wherein a number of the plurality of regions of the polishing object is equal to a number of the plurality of temperature sensors.

5. The polishing process apparatus of claim 3, wherein each of the plurality of regions of the polishing object has a concentric circle shape with respect to the rotation axis.

6. The polishing process apparatus of claim 5, wherein a width of each of the plurality of regions decreases as a distance from the rotation axis increases.

7. The polishing process apparatus of claim 6, wherein a distance between adjacent temperature sensors, among the plurality of temperature sensors, decreases as a distance from the rotation axis increases.

8. A polishing process apparatus, comprising:
a carrier including a polishing head configured to receive a polishing object, a drive shaft configured to rotate the polishing head, and a temperature sensor mounting portion connected to the drive shaft;
a polishing pad on a lower portion of the carrier;
a plurality of temperature sensors on the temperature sensor mounting portion; and
a controller configured to control the carrier, the polishing pad, and the plurality of temperature sensors,
wherein the polishing head has a first radius from a central axis of the polishing head,
the plurality of temperature sensors are configured along an arc having a second radius from the central axis of the polishing head, and the second radius has a value greater than that of the first radius, and
the controller is configured to determine an end point in time of a polishing process using temperatures measured by the plurality of temperature sensors.

9. The polishing process apparatus of claim 8, wherein in a radial direction, parallel to an upper surface of the polishing head and extending away from the central axis of the polishing head, a distance between adjacent temperature sensors on an outside of the plurality of temperature sensors, relative to the central axis, is shorter than the second radius.

10. The polishing process apparatus of claim 9, wherein the plurality of temperature sensors are configured to measure a temperature of the polishing pad.

11. The polishing process apparatus of claim 10, wherein the controller is configured to determine a temperature of a portion of the polishing pad in contact with the polishing object, using the temperatures measured by the plurality of temperature sensors.

12. The polishing process apparatus of claim 11, wherein
the polishing object includes a plurality of regions, and
the controller is configured: to determine a temperature of a portion of the polishing pad in contact with each of the plurality of regions of the polishing object, using the temperatures measured by the plurality of temperature sensors; to calculate respective temperature change data for each of the plurality of regions based on the temperatures measured by the plurality of temperature sensors; and to determine the end point in time of the polishing process based on the respective temperature change data.

13. The polishing process apparatus of claim 12, wherein each of the plurality of regions of the polishing object has a concentric circle shape with respect to the central axis.

14. The polishing process apparatus of claim 13, wherein a width of each of the plurality of regions of the polishing object decreases as a distance from the central axis increases.

15. The polishing process apparatus of claim 9, wherein each of the plurality of temperature sensors has a same height from the polishing pad, in a vertical direction perpendicular to an upper surface of the polishing pad.

16. A polishing process apparatus, comprising:
a carrier including a polishing head configured to receive a polishing object;
a polishing pad on a lower portion of the carrier;
a plurality of temperature sensors on the carrier; and
a controller configured to control the carrier, the polishing pad, and the plurality of temperature sensors,
wherein the polishing object includes a plurality of regions,
the plurality of temperature sensors are configured to respectively measure temperatures corresponding to the plurality of regions of the polishing object, different from each other, while a polishing process is performed, and
the controller is configured to receive the temperatures from the plurality of temperature sensors and derive temperature data, to calculate temperature change data using the temperature data, and to determine an end point in time of a polishing process using the temperature change data.

17. The polishing process apparatus of claim 16, wherein the temperature data includes temperatures detected at different points in time with respect to each of the plurality of regions of the polishing object.

18. The polishing process apparatus of claim 16, wherein the temperature change data includes amounts of temperature change respectively detected in the plurality of regions of the polishing object during a predetermined period of time.

19. The polishing process apparatus of claim 18, wherein the controller is configured to calculate the temperature change data by differentiating the temperature data with respect to time.

20. The polishing process apparatus of claim 16, wherein the end point in time of the polishing process is a latest point in time, among points in time when amounts of temperature change of the plurality of regions of the polishing object respectively converge to zero, after a point in time at which the amounts of temperature change of the plurality of regions of the polishing object respectively have a maximum value.
